(19) United States
(12) Patent Application Publication
(10) Pub. No.: US 2010/0109084 A1
(43) Pub. Date: May 6, 2010

(54) Semiconductor Device and Method for Fabricating the Same

(75) Inventor: Su Ock Chung, Seoul (KR)

Correspondence Address: MARSHALL, GERSTEIN & BORUN LLP, 233 SOUTH WACKER DRIVE, 6300 SEARS TOWER, CHICAGO, IL, 60606-6357, US

(73) Assignee: HYNIX SEMICONDUCTOR INC., Icheon-si (KR)

(21) Appl. No.: 12/345,107

(22) Filed: Dec. 29, 2008

(30) Foreign Application Priority Data
Oct. 30, 2008 (KR) 10-2008-0107138

(51) Int. Cl. H01L 29/772; H01L 21/28

(52) U.S. Cl. 257/347; 438/592; 257/E21.19; 257/E29.242

(57) ABSTRACT

Disclosed herein is a semiconductor device having an enhanced floating body and a fabrication method for increasing operational stability of the device. The method includes depositing a fin structure on a silicon-on-insulator, forming a gate pattern covering the fin structure, and forming conductive regions in the silicon-on-insulator exposed at both sides of the gate pattern to compartmentalize a floating body of each transistor.

### CROSS-REFERENCES TO RELATED APPLICATION

The priority benefit of Korean patent application No. 10-2008-0107138, filed on Oct. 30, 2008, is hereby claimed and the disclosure thereof is incorporated by reference in its entirety.

### BACKGROUND OF THE INVENTION

1. Field of Invention

The present invention generally relates to a method for fabricating a semiconductor device, and more specifically, to the formation of a floating body transistor used in a highly-integrated semiconductor device using a silicon-on-insulator (SOI).

2. Brief Description of Related Technology

In a system constituted with a plurality of semiconductor devices, a semiconductor memory apparatus is configured to store data generated or processed therein. For example, if a request from a data processor such as a central processing unit (CPU) is received, the semiconductor memory apparatus outputs data to a data processor from unit cells therein or stores data processed by the data processor to the unit cells, according to an address transmitted with the request.

Recently, data storage capacity of semiconductor memory apparatus have increased, but the size of these apparatus has not increased proportionally. Thus, various elements and components used for read or write operations in the apparatus have also reduced in size. Accordingly, components and elements duplicated unnecessarily in the apparatus, such as transistors or wires, are combined or merged to reduce the area occupied by each component. Particularly, the reduction of the size of unit cells included in the semiconductor memory apparatus affects improvement of integration.

Dynamic Random Access Memory (DRAM) is a type of volatile memory device configured to retain data while a power source is supplied. The unit cell includes a transistor and a capacitor. In the case of the unit cell having a capacitor, after the data “1” is delivered to the capacitor, charges that are temporarily stored in the storage node are dissipated (i.e., the amount of the charges stored therein are reduced). Charges dissipate because of both leakage current generated at the junction of the storage node, and the inherent characteristic of the capacitor, which actually loses charges over time. As a result, a refresh operation is periodically required on the unit cells so that data stored in the DRAM will not be destroyed.

To prevent the reduction of charges, numerous methods for increasing capacitance (Cs) of the capacitor included in the unit cell have been suggested so that more charges may be stored in the storage node. For example, a prior insulating film of the capacitor (e.g., an oxide film) is replaced with an advanced insulating film, which has a larger dielectric constant, such as a nitrified oxide film or a high dielectric film. Alternatively, the capacitor having a two-dimensional structure is replaced to have a three-dimensional cylinder structure or a trench structure, thereby increasing the surface area of both electrodes of the capacitor.

As the design rule is reduced, the plane area where a capacitor can be formed is reduced, and it is difficult to develop materials for constituting an insulating film in the capacitor. As a result, the junction resistance value of the storage node (SN) and the turn-on resistance value of the transistor in the unit cell are larger, it is difficult to perform normal read and write operations, and refresh characteristics deteriorate. To improve these shortcomings, the unit cell includes a transistor having a floating body. That is, the unit cell of the semiconductor memory apparatus does not include a capacitor used for storing data; but, instead stores data in a floating body of the transistor included in the unit cell.

FIGS. 1a to 1e are cross-sectional diagrams illustrating a method for manufacturing a floating body transistor in a conventional semiconductor memory apparatus. A semiconductor memory apparatus including a floating body transistor includes a lower semiconductor substrate (not shown), a lower insulating oxide layer 102 formed over the lower semiconductor substrate, and a silicon-on-insulator (SOI) wafer including a silicon active region 101 formed over the lower insulating oxide layer 102. The SOI wafer is a wafer where an insulating layer is artificially formed between the surface and a basic layer to remove the impact from the basic layer, thereby improving the process, efficiency and characteristics of a high-pure silicon layer formed over the insulating layer. The SOI wafer provides a zero-defective thin silicon layer isolated with an insulating material (thermal oxide film) and, therefore, an insulating wall or a well-forming process is not required, so that the product developing and producing time and cost are reduced. Also, there is no burden on equipment investment because the equipment that uses a general wafer reduces unnecessary equipment.

Referring to FIG. 1b, a gate oxide film 103 is formed over the silicon active region 101. Thereafter a gate lower electrode 104, a gate upper electrode 105, and a gate hard mask film 106 are sequentially deposited over the gate oxide film 103, as shown in FIG. 1c. The gate hard mask film 106, the gate upper electrode 105, the gate lower electrode 104, and the gate oxide film 103 are sequentially etched to form a gate pattern. After the gate pattern is formed, a gate spacer 107 is formed at sidewalls of the gate pattern as shown in FIG. 1d.

Referring to FIG. 1e, impurities are doped between the gate patterns, and thermally treated to form a conductive region 108, thereby isolating the two neighboring floating body transistors. The conductive region 108 is formed to have contact with the lower insulating oxide layer 102 located in a lower portion of the silicon active region 101. Although the size of the floating body transistor is reduced and a gap between the neighboring floating body transistors is minimized, the neighboring floating body transistors are isolated through the conductive region 108 without sharing of the floating body region. As a result, the integration of the semiconductor device including the floating body transistor is improved.

As shown in FIG. 1e, while the conductive region 108 is extended to a lower portion of the gate pattern in a horizontal direction through the thermal treatment, an effective channel length 109 of the floating body transistor is shorter, and the volume of the floating body is reduced. When the effective channel length 109 of the floating body transistor is shorter, a short channel effect such as a punch-through phenomenon is generated to degrade operational stability.

When the floating body transistor is used as a cell transistor for constituting unit cells in the semiconductor memory apparatus, the punch-through phenomenon causes mis-operations. If the volume of the floating body is reduced, the number of holes accumulated in the floating body corresponding to stored data is reduced. The volume reduction of the floating body decreases the capacity of storing data in the unit cell over a long duration, and a sensing margin for distinguishing data “0” from data “1” is reduced to degrade the refresh characteristic. That is, the operational margin of the unit cell in the semiconductor memory apparatus is reduced.

### BRIEF SUMMARY OF THE INVENTION

Various embodiments of the present invention are directed at providing a semiconductor device and a fabrication method for increasing operational stability by forming a fin structure formed on a thin silicon layer of silicon-on-insulator (SOI) through epitaxial growth to thereby enlarge the volume of a floating body and prevent a decrease of the effective channel length.

In accordance with an aspect of the invention, there is provided a method for fabricating a semiconductor device that includes: depositing a fin structure on a silicon-on-insulator, forming a gate pattern covering the fin structure, and forming conductive regions in the silicon-on-insulator exposed at both sides of the gate pattern to compartmentalize a floating body of each transistor.

Preferably, the -pin structure can be deposited by forming a sacrificial layer on the silicon-on-insulator, patterning the sacrificial layer through a photo-lithography process using a mask defining a position of the fin structure, enlarging an active silicon layer in the silicon-on-insulator exposed by patterned sacrificial layer through an epitaxial growth, and removing the patterned sacrificial layer. Preferably, a dopant-doped silicon is used in the epitaxial growth.

Preferably, the silicon-on-insulator includes a buried insulator formed under the active silicon layer and a silicon substrate formed under the buried insulator.

Preferably, the floating body includes the fin structure and the active silicon layer between the conductive regions.

The method may further include forming a gate oxide layer on the fin structure and the silicon-on-insulator.

Preferably, the gate pattern can be formed by forming a first gate electrode on the gate oxide layer, forming a second gate electrode on the first gate electrode, forming a gate hard mask on the second gate electrode, and etching the gate hard mask, the second gate electrode, the first gate electrode, the gate oxide layer by using a gate mask.

The method may further include forming a spacer at sidewalls of the gate pattern.

The conductive regions can be formed by injecting a dopant into the silicon-on-insulator exposed at both sides of the gate pattern, and performing a thermal process on the silicon-on-insulator to spread the dopant to a buried insulator of the silicon-on-insulator.

In accordance with another aspect of the invention, there is provided a semiconductor device that includes a floating body, which includes an epitaxial layer formed on a silicon-on-insulator as a fin structure and an active silicon layer of the silicon-on-insulator compartmentalized by conductive regions. The floating body is configured to store a hot carrier generated depending on transmitted data. The device also includes a gate pattern, which covers the epitaxial layer, and is configured to make a channel in the epitaxial layer according to supplied voltage.

The semiconductor device may further include a gate oxide layer between the floating body and the gate pattern. The semiconductor device also may further include a spacer at both sidewalls of the gate pattern.

Preferably, a minimum thickness of the epitaxial layer is greater than 50% to 100% than that of the active silicon layer.

In accordance with another aspect of the invention, there is provided a method for fabricating a semiconductor device that includes forming a sacrificial layer pattern on a silicon-on-insulator, depositing a fin structure by enlarging an active silicon layer in the silicon-on-insulator exposed by the sacrificial layer pattern through an epitaxial growth, and, forming a gate pattern covering the fin structure. The method may further include forming a spacer at sidewalls of the gate pattern.

Preferably, formation of the gate pattern includes forming a first gate electrode on the gate oxide layer, forming a second gate electrode on the first gate electrode, forming a gate hard mask on the second gate electrode, and etching the gate hard mask, the second gate electrode, the first gate electrode, and the gate oxide layer with a gate mask.

The method may further include forming conductive regions in the silicon-on-insulator exposed at both sides of the gate pattern to compartmentalize a floating body of each transistor.

Additional features of the disclosed invention may become apparent to those skilled in the art from a review of the following detailed description, taken in conjunction with the drawings, and the appended claims.

For a more complete understanding of the disclosure, reference should be made to the following detailed description and accompanying drawings wherein:

### BRIEF DESCRIPTION OF THE DRAWINGS

FIGS. 1a to 1e are cross-sectional diagrams illustrating a method for manufacturing a floating body transistor in a general semiconductor memory apparatus.

FIG. 2a to 2g are cross-sectional diagrams illustrating a method for manufacturing a floating body transistor in a semiconductor memory apparatus according to an embodiment of the present invention.

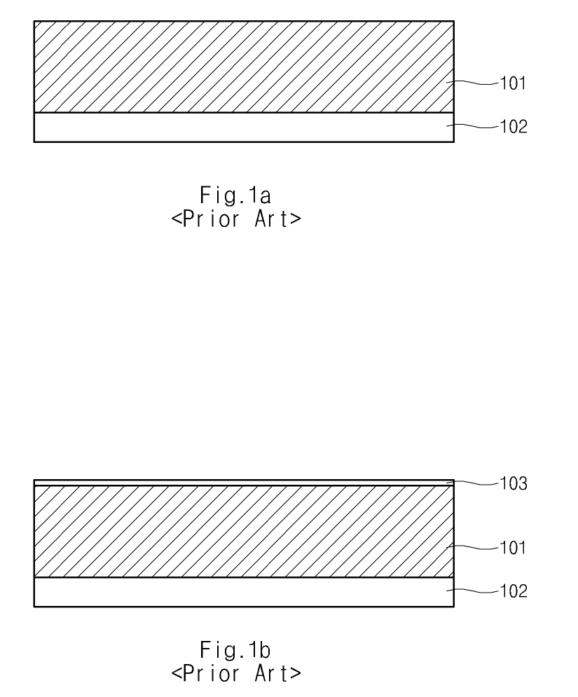

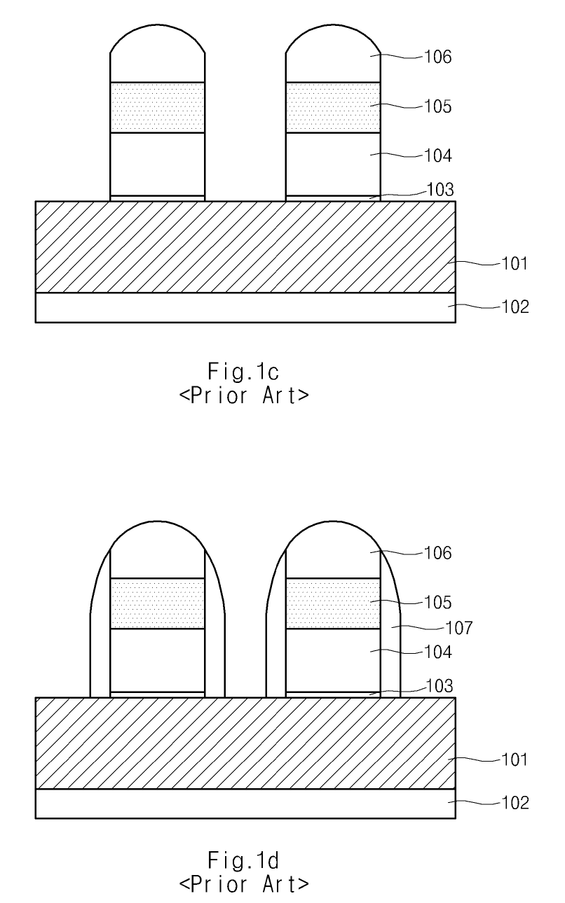

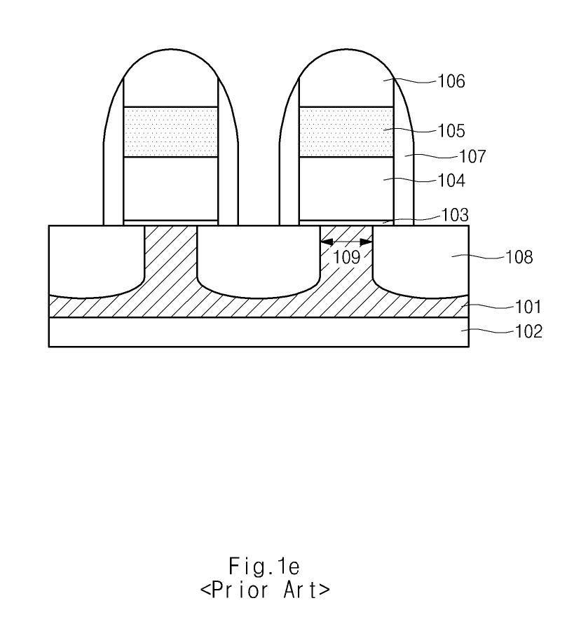

While the disclosed device and method are susceptible of embodiments in various forms, there are illustrated in the drawings (and will hereafter be described) specific embodiments thereof, with the understanding that the disclosure is intended to be illustrative, and is not intended to limit the device and method to the specific embodiments described and illustrated herein.

### DETAILED DESCRIPTION

A semiconductor memory apparatus including a floating body transistor according to an embodiment of the present invention overcomes disadvantages revealed when the floating body transistor is formed on a silicon-on-insulator (SOI) as well as obtains equivalent effects to those formed on a silicon bulk substrate in view of body volume and effective channel length. Hereinafter, preferred embodiments of the invention will be described in detail with reference to the accompanying drawings.

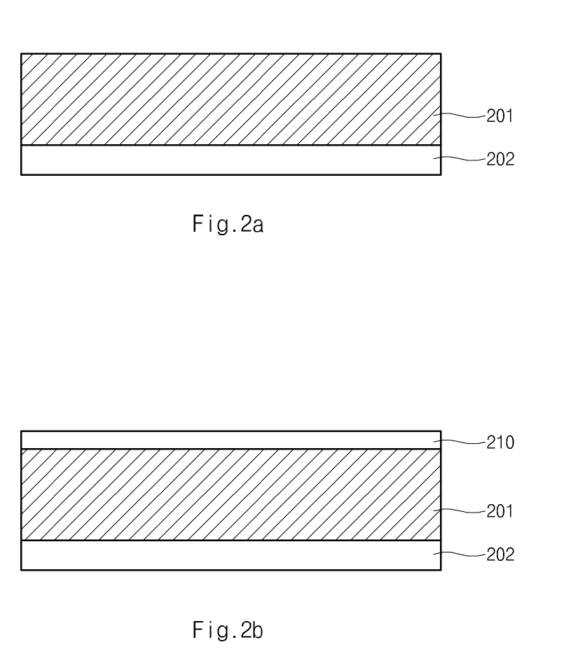

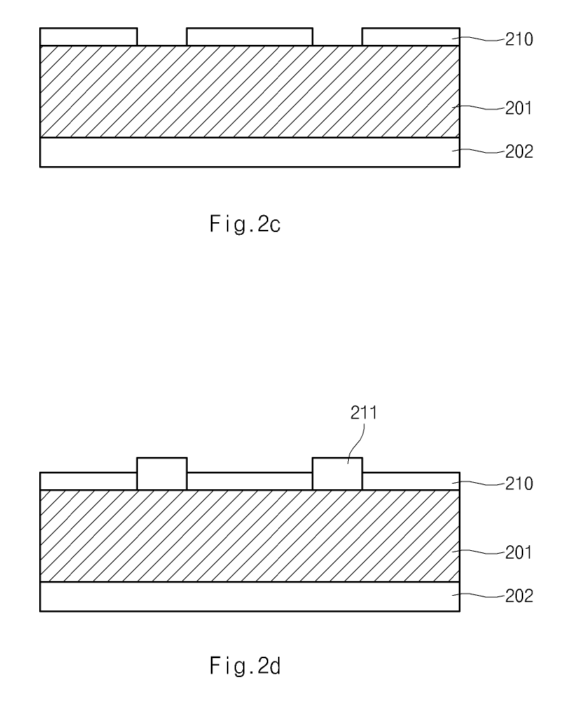

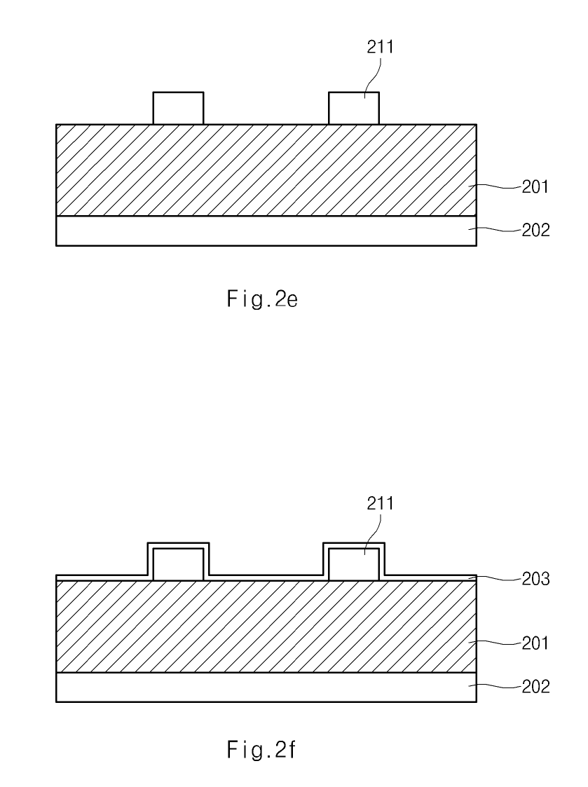

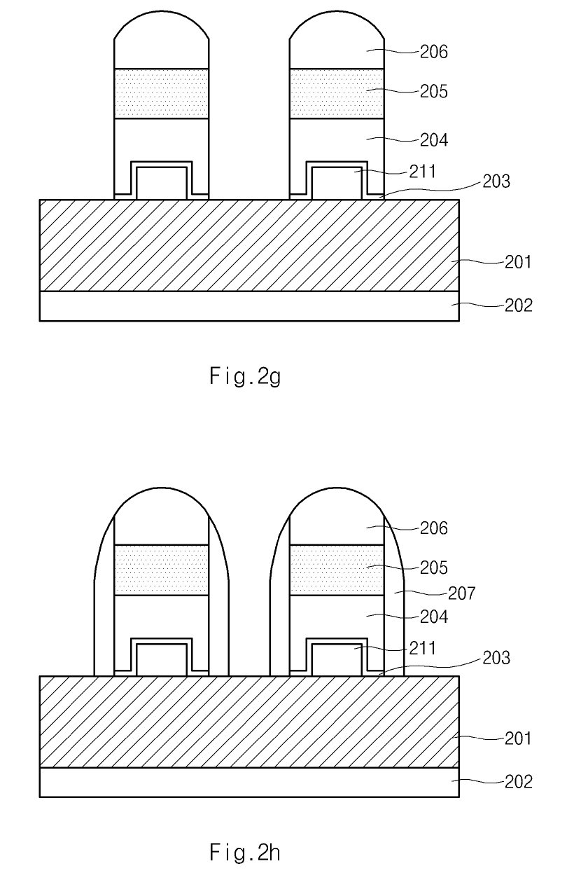

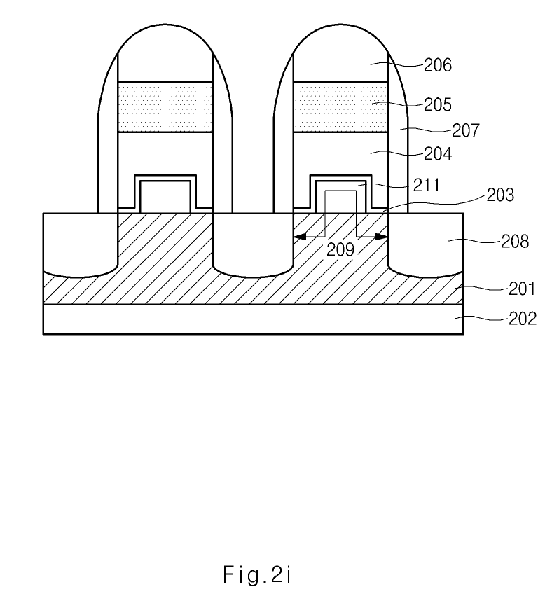

FIG. 2a to 2g are cross-sectional diagrams illustrating a method for manufacturing a floating body transistor in a semiconductor memory apparatus according to an embodiment of the present invention. Referring to FIG. 2a, the semiconductor memory apparatus including a floating body transistor comprise a lower semiconductor substrate (not shown), a lower insulating oxide layer 202 formed over the lower semiconductor substrate, and a SOI wafer including a silicon active region 201 formed over the lower insulating oxide layer 202. Herein, the silicon active region 201 of the SOI substrate which is thinner than that of a conventional SOI substrate is used in the embodiment of the present invention.

As shown in FIG. 2b, a sacrificial film 210 is formed over the silicon active region 201.

Referring to FIG. 2c, after a photoresist film (not shown) is coated over the sacrificial film 210, a mask that defines a fin region is patterned through a photo process. The sacrificial film 210 exposed between the patterned photoresist films is etched to expose a portion of the active region 201.

As shown in FIG. 2d, based on the silicon active region 201 exposed between the sacrificial film 210, a silicon epitaxial growth (SEG) process for growing a silicon in a single direction is performed to form a fin region 211. After the fin region 211 is formed, the residual sacrificial film 210 is removed as shown in FIG. 2e. When a pure silicon, which is not doped with impurities, is used in the SEG process, an additional ion-implanting process is performed to form a channel region. However, when a SEG process is performed with a silicon doped with impurities, an additional ion-implanting process for forming a channel region is not performed.

Referring to FIGS. 2f and 2g, a gate oxide film 203 is formed over the resulting structure including the fin region 211. A gate lower electrode 204, a gate upper electrode 205 and a gate hard mask film 206 are sequentially deposited over the gate oxide film 203. As shown in FIG. 2g, the gate hard mask film 206, the gate upper electrode 205, the gate lower electrode 204, and the gate oxide film 203 are sequentially etched to form a gate pattern. When the gate pattern is formed to surround the upper portion and the side surface of the fin region 211, the structure of the floating body fin transistor can be obtained.

After the gate pattern is formed, as shown in FIG. 2h, a gate spacer 207 is formed at both sidewalls of the gate pattern. The spacer 207 protects the gate pattern, and reduces leakage current from the gate electrode to improve operation characteristics of the transistor.

Referring to FIG. 2i, impurities are doped between the gate patterns, and a thermal treatment process is performed to form the conductive region 208, thereby isolating the two neighboring floating body transistors. The thermal treatment process is performed so that the conductive region 208 may contact the lower insulating oxide layer 202 located in a lower portion of the silicon active region 201. Although the size of the floating body transistor is reduced and the gap between the neighboring floating body transistors is minimized, neighboring floating body transistors are isolated through the conductive region 208 without sharing the floating body region. As a result, the integration of the semiconductor device including the floating body transistor is improved.

Unlike the prior art, in the present invention, a floating body transistor is fabricated with a SOI substrate having a thin silicon active region. Generally, if the volume of the floating body is reduced, it is difficult to store holes generated by hot carriers so that stable operation of the floating body transistor cannot be secured. However, a fin region formed of an epitaxial layer is further included over the SOI substrate in the present invention, which is not limited in the silicon active region 201 over the SOI substrate. In the present invention, the fin region 211 is included so that the volume of the floating body may be the same as that when the less thin SOI substrate is used.

When the thin SOI substrate is used, thermal treatment time for forming the conductive region 208 is short. When the thickness of the silicon active region 201 is thin during implantation of impurities between the gate patterns and diffusion through the thermal treatment process, it is easy to diffuse impurities into the lower insulating oxide layer 202 buried in the lower portion. When the thermal treatment time is reduced, the horizontal diffusion of the conductive region is also reduced, thereby preventing a channel region, which is formed in the lower portion of the gate pattern, from being shorter by the conductive region 208.

As shown in FIG. 2i, because the thermal treatment time is reduced with formation of the fin region 211, the effective channel length 209 is sufficiently secured, thereby preventing mis-operations by the short channel effect. As a result, when the floating body fin transistor formed according to the disclosed method is applied to a unit cell of a semiconductor memory apparatus, stability of the operation can be secured, and integration may be improved.

Although a thin SOI substrate is used, the volume of the body region including the fin region 211 is increased by a silicon formed through a SEG process, so that it is easy to secure the volume of the body that may secure the stable operation of the floating body transistor. In the case of a commercialized SOI substrate, the thickness of the buried lower insulating oxide layer ranges from about 20 nm to about 200 nm, and the thickness of the silicon active region formed over the lower insulating oxide layer ranges from about 50 nm to about 150 nm. It is not preferable to increase the thickness of the silicon active region due to decrease of productivity occurred by technical limits and rising cost. The thickness of the silicon active region used as a body of a conventional floating body fin transistor is so thin that holes generated by hot carriers may not be stored. However, in the case of the semiconductor device fabricated by the disclosed method, the volume of the floating body transistor is increased by the silicon formed through the SEG process, so that holes generated by hot carriers may be stored. Specifically, the thickness of the body of the floating body transistor is increased by 50% to 100% by formation of the fin region, thereby preventing mis-operations due to the short channel effect.

The above embodiments of the present invention are illustrative and not limitative. Various alternatives and equivalents are possible. The invention is not limited by the type of deposition, etching polishing, and patterning steps describe herein. Nor is the invention limited to any specific type of semiconductor device. For example, the present invention may be implemented in a dynamic random access memory (DRAM) device or non volatile memory device. Other additions, subtractions, or modifications are obvious in view of the present disclosure and are intended to fall within the scope of the appended claims.

What is claimed:

1. A method for fabricating a semiconductor device, the method comprising:
depositing a fin structure on a silicon-on-insulator;
forming a gate pattern covering the fin structure; and
forming conductive regions in the silicon-on-insulator exposed at both sides of the gate pattern to compartmentalize a floating body of each transistor.

2. The method according to claim 1, wherein the deposition of the -pin structure comprises:
forming a sacrificial layer on the silicon-on-insulator;
patterning the sacrificial layer through a photo-lithography process using a mask defining a position of the fin structure;
enlarging, through an epitaxial growth, an active silicon layer in the silicon-on-insulator exposed by the patterned sacrificial layer; and
removing the patterned sacrificial layer.

3. The method according to claim 2, wherein a dopant-doped silicon is used in the epitaxial growth.

4. The method according to claim 2, wherein the silicon-on-insulator comprises a buried insulator formed under the active silicon layer and a silicon substrate formed under the buried insulator.

5. The method according to claim 4, wherein the floating body includes the fin structure and the active silicon layer between the conductive regions.

6. The method according to claim 1 further comprising forming a gate oxide layer on the fin structure and the silicon-on-insulator.

7. The method according to claim 6, wherein formation of the gate pattern comprises:
forming a first gate electrode on the gate oxide layer;
forming a second gate electrode on the first gate electrode;
forming a gate hard mask on the second gate electrode; and
etching the gate hard mask, the second gate electrode, the first gate electrode, and the gate oxide layer with a gate mask.

8. The method according to claim 1 further comprising forming a spacer at sidewalls of the gate pattern.

9. The method according to claim 1, wherein formation of the conductive-regions includes:
injecting a dopant into the silicon-on-insulator exposed at both sides of the gate pattern; and
performing a thermal process on the silicon-on-insulator to spread out the dopant to a buried insulator of the silicon-on-insulator.

10. A semiconductor device comprising:
a floating body comprising an epitaxial layer formed on a silicon-on-insulator as a fin structure and an active silicon layer of the silicon-on-insulator compartmentalized by conductive regions, the floating body configured to store a hot carrier; and,
a gate pattern covering the epitaxial layer, the gate pattern configured to make a channel in the epitaxial layer according to supplied voltage.

11. The semiconductor device according to claim 10 further comprising a gate oxide layer between the floating body and the gate pattern.

12. The semiconductor device according to claim 10 further comprising a spacer at both sidewalls of the gate pattern.

13. The semiconductor device according to claim 10, wherein a minimum thickness of the epitaxial layer is greater than 50% to 100% of the thickness of the active silicon layer.

14. A method for fabricating a semiconductor device, the method comprising:
forming a sacrificial layer pattern on a silicon-on-insulator;
depositing a fin structure by enlarging, through an epitaxial growth, an active silicon layer in the silicon-on-insulator exposed by the sacrificial layer pattern; and
forming a gate pattern covering the fin structure.

15. The method according to claim 14 further comprising forming a spacer at sidewalls of the gate pattern.

16. The method according to claim 15, wherein formation of the gate-pattern comprises:
forming a first gate electrode on the gate oxide layer;
forming a second gate electrode on the first gate electrode;
forming a gate hard mask on the second gate electrode; and
etching the gate hard mask, the second gate electrode, the first gate electrode, the gate oxide layer with a gate mask.

17. The method according to claim 14 further comprising forming conductive regions in the silicon-on-insulator exposed at both sides of the gate pattern to compartmentalize a floating body of each transistor.
